(19) United States
(12) Patent Application Publication
(10) Pub. No.: US 2015/0007891 A1
(43) Pub. Date: Jan. 8, 2015

(54) POLYMER SOLAR CELL WITH NANOPARTICLES

(71) Applicant: INSTITUTE OF NUCLEAR ENERGY RESEARCH ATOMIC ENERGY COUNCIL, EXECUTIVE YUAN, TAOYUAN COUNTY (TW)

(72) Inventors: WEI-FANG SU, Taipei City (TW); HSUEH-CHUNG LIAO, Taipei City (TW); TSUNG-HAN LIN, Taipei City (TW); CHIH-MIN CHUANG, TAOYUAN COUNTY (TW)

(21) Appl. No.: 13/934,339

(22) Filed: Jul. 3, 2013

(51) Int. Cl. H01L 51/42

(52) U.S. Cl. CPC H01L 51/426
USPC 136/263

(57) ABSTRACT

A polymer solar cell is disclosed, which comprises: a substrate, made of a transparent glass material; a transparent bottom electrode, disposed on the substrate; a hole transport layer, arranged on the bottom electrode by the use of a solution process, such as spin coating or spray printing; and an active layer, arranged on the hole transport layer and provided to be doped with a trace concentration of nanoparticles, that is acting as additives; wherein, after being doped with the nanoparticles and treated by an annealing treatment, the power conversion efficiency of the active layer is enhanced.

### FIELD OF THE INVENTION

The present invention generally relates to a polymer solar cell, and more particularly, to a polymer solar cell that is doped with an additive of nanoparticles for achieving power conversion efficiency enhancement.

### BACKGROUND OF THE INVENTION

Nowadays, it is generally acknowledged that there is still much to be improved on solar cells both in cost and performance, not matter it is a wafer-based solar cell or a thin film solar cell. Comparatively, the polymer solar cells, which are considered more technically advanced, are advantageous in that the polymer solar cells are inexpensive to fabricate. Thus, with the advance in technology, the future polymer solar cell that is armed with better cell efficiency and reliability can be sure to become a strong competitor in solar cell industry.

It is noted that the synthesis of organic-inorganic hybrid nanoparticles can be achieved by the use of an ion process or a sol-gel process. Nevertheless, during the synthesis, the inorganic nanoparticles should be evenly dispersed in an organic solvent while being distributing uniformly in size. Currently, there are already many techniques available for synthesizing and transferring certain types of inorganic nanoparticles to an organic phase, e.g. CdSe nanoparticles, Cu₂S nanoparticles, TiO₂ nanoparticles, and Au nanoparticles. Generally, the synthesis is performed first by mixing precursors of a nano-material with a reaction solvent and surface ligands that are capable of assisting the distribution of the nano-material, and then by subjecting the foregoing precursor composition to an environment of suitable temperature for allowing nanoparticles to grow therein. After the synthesis is completed, it is importance to perform a purification process upon the synthesized nanoparticles, whereas the purification process further comprises a standard solvent-nonsolvent centrifugal separation procedure that is to be used for removing excess organic matters from the synthesized nanoparticles. Such standard solvent-nonsolvent centrifugal separation procedure is essential for removing excess organic matters from the synthesized nanoparticles that are to be doped into polymer solar cells, since if there are still excess organic matters contained in the nanoparticles, the electron transmission in the thin film of the solar cell can be impeded thereby as the organic matters are generally electrical insulations that does not respond to an electric field and can completely resist the flow of electric charge.

Please refer to FIG. 1, which shows a conventional solar cell with bulk heterojunction structure in cis-configuration. As shown in FIG. 1, the solar cell 1′ is formed as a layer-by-layer structure, which comprises: a substrate 2′, a transparent bottom electrode 3′, arranged on the substrate 2′; a hole transport layer 4′, coated on the transparent bottom electrode 3′ by a solution process; and an active layer 5′, being a thin film doped with donors and acceptors that is disposed on the hole transport layer 4′. Moreover, the active layer 5′ of the polymer solar cell 1′ can be made of a material of p-n structure, such as poly(3-hexylthiophene)/(6,6)-phenyl C61-butyric acid methyl ester (PCBM), whichever has the advantages of low cost, light weight, flexibility, and can be used easily for manufacturing large-area photovoltaic devices.

Surface morphology is the key factor that can determine the energy conversion efficiency for polymer thin-film solar cells. In those devices with bulk heterojunction structure, donors (e.g. conductive polymer) that are in one phase and acceptors (e.g. derivatives of Carbon-60 or nanoparticles) that are in another phase are mixed and doped in a thin film. Nevertheless, it is noted that although there will be a large contact area being created between the donors and the acceptors if the donors in one phase and the acceptors in another phase are well dispersed between each other, there are consequently an excess amount of interphase interfaces to be caused that are going to impede electric charges to transmit to bottom electrode and top electrode, and thus cause the performance of the resulting solar cell to deteriorate, as shown in FIG. 4. On the other hand, if the donors in one phase and the acceptors in another phase are not dispersed well and are badly separated from each other, the contact area between two phases of the donors and the acceptors is so small that short-circuit might be caused. In addition, the transportation of electric charges can also be affected by the crystallinity and ordered structure of polymer itself, e.g. mobility. Therefore, a topic of how to optimize surface morphology to acquire appropriate phase separation, bi-continuous routes, and good polymer stack so as to achieve best cell performance is extensively researched and discussed.

The most extensively researched materials in polymer thin film solar cell are poly(3-hexylthiophene) (P3HT) and derivatives of Carbon-60 (PCBM). Different solvents for causing different phase separations, including chlorobenzene and chloroform, are used and tried in order to optimize the surface morphology of polymer thin film. However, the most effective method that is found today is to heat the materials of a polymer, such as P3HT and the PCMB, to a suitable temperature for a specific period of time so as to optimize the surface morphology thereof. Consequently, the polymer P3HT in the heating process can be crystallized into an ordered structure while the PCBM is being gathered into clusters of suitable size, resulting that the power conversion efficiency of the solar cell is obviously improved. Based upon the aforesaid technique, the present invention intends to further improve the optimization of the surface morphology in polymer thin film by adding a minute amount of inorganic nanoparticles as additives into the polymers that are being treated by the heating process, resulting that the cluster size of the PCBM is optimized so as to further improve performance of the solar cells.

There are already many researches and documents indicated that the energy conversion efficiency of solar cells is decisively influenced by the thin-film surface morphology formed by polymer and acceptors. In addition, there are many manufacturing processes available today for creating a most suitable route in the thin film for carrier transport, whereas those manufacturing processes includes thermal annealing, solvent annealing, or process of entering additives, etc. For instance, the efficiency of the mixture of the aforesaid P3HT/PCBM can be improved greatly by a heating process.

With the advance in solar cell technology, there are already many different type of solar cells available, which include several systems, e.g. Si-based solar cells, group III-V solar cells, dye-sensitized solar cells, and organic thin film solar cells, and so on. Among which the potential of the organic thin film solar cells, which adopt polymers as light-absorbing materials, is most highly valued, since the organic thin film solar cell has the following advantages: it is low in cost as it can be manufactured using a solvent process at room temperature; and in addition, as the flexible characteristic of the polymer materials enables the polymer structure of the thin film polymer solar cells to be formed on a flexible substrate, the usefulness and application of the so-constructed thin film polymer solar cells are widened accordingly. However, the biggest problem of the thin film polymer solar cell is its low power conversion efficiency. Nevertheless, for the most extensively researched polymer material (P3HT and PCBM), although its power conversion efficiency can reach 4% to 5%, as disclosed in Adv. Funt. Mater., 2005, vol15, p1617, by Hegger A J, and Nature Materials, vol4, p864, 2005, by Yang Y, such acceptable power conversion efficiency is achieved under the increasing cost an labor of many additional manufacturing processes and operations, and thus it is relatively not economically attractive and viable.

Although the aforesaid technique for improving energy conversion efficiency can be applied in solar cells using different polymer materials, the energy conversion efficiency can only be improved to a certain extend since the light-absorbing range of P3HT is limited to the waveband of visible light that most energy contained in the near infrared (NIR) light is not absorbed by the P3HT. Recently, by the development in polymer structure design and synthesis techniques, there are already several conductive polymers being developed, which are formed with low energy band gap for absorbing the part of sunlight with longer wavelength. However, for such polymers which are disclosed in up-to-date reports and papers, neither their surface morphology in thin film formation can not be effectively optimized by solvent process or heating process, nor the performance of the resulting solar cells can be improved effectively by the same. Therefore, the present invention intends to further improve the optimization of the surface morphology in polymer thin film by adding a minute amount of inorganic nanoparticles as additives into the polymers.

### SUMMARY OF THE INVENTION

The objective of this invention is to provide a polymer solar cell that can achieve a comparatively higher energy conversion efficiency by the doping of an additive of nanoparticles in micro concentration into the active layer of the solar cell without having to incorporate any additional process to the manufacture process of the solar cell.

To achieve above objective, the present invention provides a polymer solar cell, which comprises: a substrate, made of a transparent glass material; a transparent bottom electrode, disposed on the substrate; a hole transport layer, arranged on the bottom electrode by the use of a solution process, such as spin coating or spray printing; and an active layer, arranged on the hole transport layer and provided to be doped with a trace concentration of nanoparticles, that is acting as additives; wherein, after being doped with the nanoparticles and treated by an annealing treatment, the power conversion efficiency of the active layer is enhanced.

In an embodiment, the trace concentration is 0.01˜01 mg ml⁻¹, and there are an electron transporting layer/hole blocking layer/optical spacer layer and a transparent top electrode that are successively arranged on the active layer in series. In addition the solution process is a mean selected from the group consisting of: a spin coating process and a spray coating process, and the nanoparticles are made of copper sulfide.

Further features and advantages of the present invention will become apparent to those of skill in the art in view of the detailed description of preferred embodiments which follows, when considered together with the attached drawings and claims.

### BRIEF DESCRIPTION OF THE DRAWINGS

All the objects, advantages, and novel features of the invention will become more apparent from the following detailed descriptions when taken in conjunction with the accompanying drawings.

FIG. 1 is a schematic diagram showing a conventional with bulk heterojunction structure in cis-configuration.

FIG. 2 is a schematic diagram showing a polymer solar cell according to an embodiment of the invention.

FIG. 3 shows pictures of nanoparticles of the present invention that are observed by a transmission electron microscopy.

FIG. 4 is a curve diagram showing the comparison of power conservation efficiency between a solar cell of the present invention and a conventional solar cell.

### DESCRIPTION OF THE PREFERRED EMBODIMENT

For your esteemed members of reviewing committee to further understand and recognize the fulfilled functions and structural characteristics of the disclosure, several exemplary embodiments cooperating with detailed description are presented as the follows.

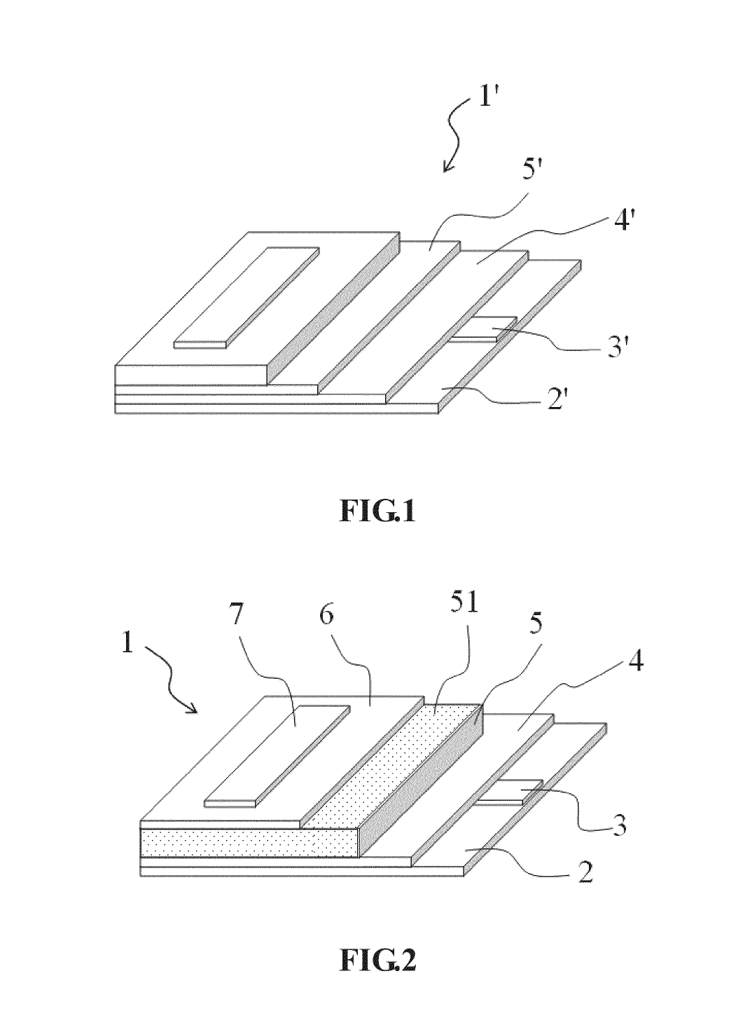

Please refer to FIG. 2, which is a schematic diagram showing a polymer solar cell according to an embodiment of the invention. It is noted that the polymer solar cell of the present invention is applicable for any type of solar cell. As shown in FIG. 2, the polymer solar cell 1 with nanoparticles comprises: a substrate 2; a transparent bottom electrode 3, disposed on the substrate 2; a hole transport layer 4, arranged on the bottom electrode 3 by the use of a solution process, such as spin coating or spray printing; and an active layer 5, arranged on the hole transport layer 4 and provided to be doped with a trace concentration of nanoparticles 51, that is acting as additives. In an embodiment, the trace concentration is 0.01˜01 mg ml⁻¹. The solvent used in the solution process should be able dissolve donors, acceptors and the nanoparticles for forming an active layer solution, and then after stirring the active layer solution overnight, and then the active layer 5, the active layer solution is prepared to be used in the solution process for coating the active layer 5 on the hole transport layer 4. It is noted that for optimizing the power conversion efficiency of the resulting solar cell, either the heat annealing treatment or even the whole manufacturing process should be selected and determined according to the type of polymer or donor used. In another embodiment, the polymer solar cell 1 can further has an electron transporting layer (or a hole blocking layer, or an optical spacer layer) 6 and a transparent top electrode 7 (formed by aluminum or transparent materials), that are arranged successively on the active layer 5 in series, so as to complete the polymer solar cell 1.

The technique for doping of nanoparticles 51 into the active layer 5 is applicable for trans bulk heterojunction materials of layer-by-layer structure, such as oxides of trans structure containing nano structures or porous structures. By the cooperation of suitable concentration and process, the doping technique can effectively optimize the morphology of the active layer 5 and the power conversion efficiency of the resulting solar cell. The steps are described as followed.

In an embodiment of the invention, nanoparticles of Cu₂S are used as the additive to be added into a P3HT/PCBM solution, and then a observation is made for evaluating the change of the power conversion efficiency after entering the additive (Cu₂S nanoparticles). The actually operation comprises the following steps:

### 1. Synthesis of Cu₂S Nanoparticles

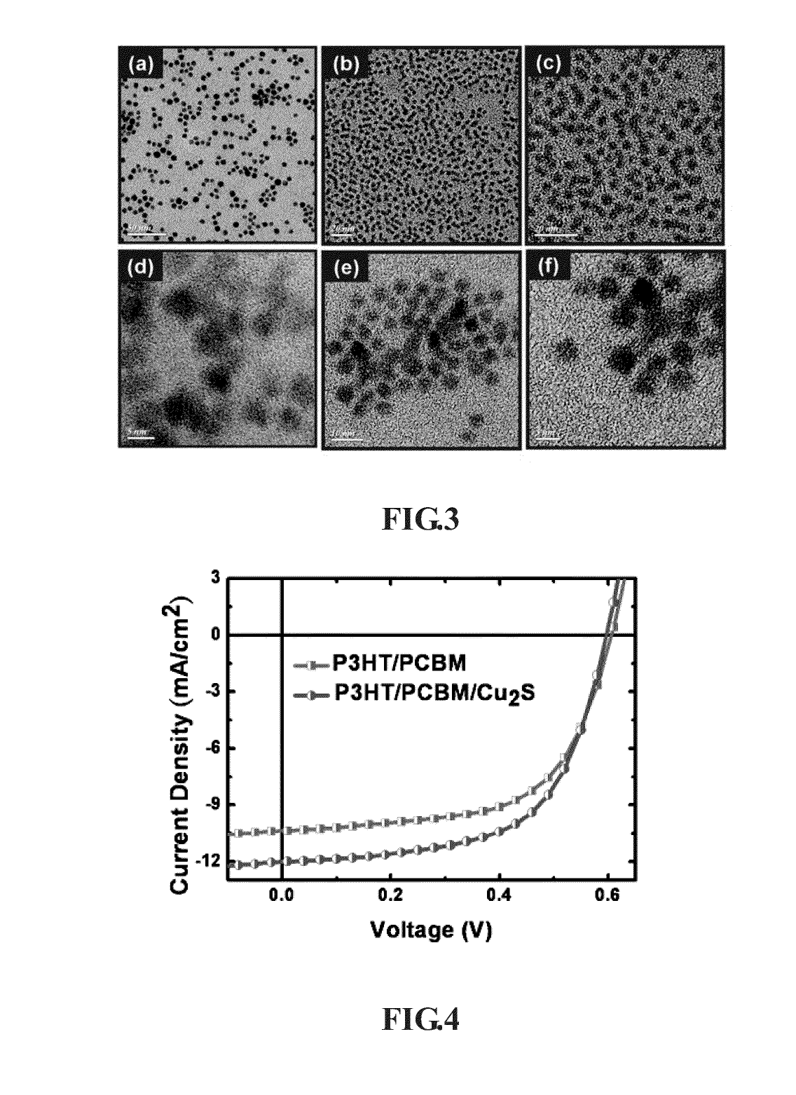

The nanoparticles made of copper sulfide are synthesized using the following steps: preparing a three-neck flask with 50 ml capacity for allowing the three necks to be respectively mounted by a condenser, a thermograph and sealed by a sleeve stopper while enabling the three-nech flask to be filled by 1.25 millimole of ammonium diethyldithiocarbamate (Aldrich), 10 ml of dodecanethiol (Aldrich, >98%) and 17 ml of oleic acid (Aldrich, 90%); mixing and stirring the aforesaid three matters in the three-neck flask in an environment filled with argon while being heated to 110° C. ; enabling 1 millimole of copper acetylacetonate (Aldrich, 99.99%) to be dispersed in 3 ml of oleic acid so as to form a blue solution while injecting the blue solution into the three-neck flask where it is heated to 180° C. and maintain at 180° C. for about 15 to 20 minutes for allowing the copper sulfide nanoparticles to grow; using a standard solvent-nonsolvent centrifugal separation process for purifying and removing excess organic matters from the nanoparticles at 4600 rpm after the temperature of the nanoparticles is dropped to 120° C.; removing the solution floating on top of the final product of the centrifugal separation process while enabling the solids deposit at the bottom of the final product to be dissolve in toluene (Acros, extra dry) under supersonic vibration; adding isopropanol (Acros, extra dry) into the solution containing the dissolved solids for segregating the nanoparticles; repeating the aforesaid steps for at least three times; and thereafter enabling the final nanoparticles to dissolve in a toluene solution so as to be keep in a grove box. Please refer to FIG. 3, which shows pictures of nanoparticles of the present invention that are observed by a transmission electron microscopy. As shown in FIG. 3, the diameter of the nanoparticles of copper sulfide is ranged between 4 nanometers to 5 nanometers that are adapted to be used in P3HT/PCBM polymer solar cells.

### 2. Preparation of the Solution of the Active Layer

The active layer is formed by the following steps: dissolving 10 mg of P3HT (Mw=69928, PDI=1.5) and 8 mg of PCBM (nano-C) in 1 ml of chlorobenzene while allowing the aforesaid mixture to be stirred and mixed for 48 hrs at 40° C. so as to prepare a P3HT/PCBM solution without nanoparticles to be used as a control group; dissolving 10 mg of P3HT and 8 mg of PCBM in 0.5 ml chlorobenzene while allowing the aforesaid mixture to be stirred and heated for 2 hrs under 40° C. so as to form an active layer solution of P3HT/PCBM/Cu₂S with Cu₂S nanoparticles to be used as a test group; performing a centrifugal separation process upon a solution formed by dissolving copper sulfide in toluene by the use of isopropanol so as to form a copper sulfide solution; adding chlorobenzene into the copper sulfide solution for preparing a new copper sulfide solution with 0.1 mg ml concentration; mixing the copper sulfide solution with 0.1 mg ml concentration with the P3HT/PCBM solution without nanoparticles, i.e. the solution of the control group, so as to form a polymer solution featuring in that: the concentration of the P3HT is 10 mg/ml, the concentration of the PCBM is 8 mg/ml and the concentration of the copper sulfide is 0.05 mg/ml; stirred and heated the polymer solution for 48 hrs in the glove box under 40° C.

### 3. Preparation of P3HT/PCBM and P3HT/PCBM/Cu₂S Solar Cells

1. A solution of HC1(Fisher Scientific, 36%) is used to etch a strip of 2.5 mm in width on the glass substrate 1 for the transparent bottom electrode 3 that is disposed on the substrate; soaking the substrate 1 in a solvent for allowing the same to be cleaned by a supersonic vibration process after etching; processing the substrate by plasma oxidation after cleaning; spin coating the (3,4-ethylenedioxythiophene)-poly(styrenesulfonate) (PEDOT:PSS) (Baytron P 4083) on the bottom electrode, that is made of indium tin oxide (ITO) so as to form a film of 60 nm in thickness; spin coating an active layer solution on the hole transport layer after drying the film along with the structure resulting from the aforesaid steps in an oven under 120° C. It is noted that either the spin coating of P3HT/PCBM solution or P3HT/PCBM/Cu₂S solution is performed at 700 rpm, whereas the difference between the P3HT/PCBM solution and the P3HT/PCBM/Cu₂S solution is only in their preheating process. That is, the preheating process for the P3HT/PCBM solution is to heat the P3HT/PCBM solution for 15 minutes under 90° C., while the preheating process for the P3HT/PCBM/Cu₂S solution is to heat the P3HT/PCBM/Cu₂S solution for 15 minutes under 110° C. And then, both are deposited using a means of evaporation deposition so as to form a 100 nm strip-like aluminum electrode in a width 2 mm under 3×10⁻⁶ torr, that can be used cooperating with the bottom electrode 3 to form a solar cell of 5 mm² area. after evaporation depositing, the device with the so-deposited aluminum electrode 7 should be processed by an annealing treatment for about 5 minutes under 150° C.

### 4. Improvement of Power Conversion Efficiency of Solar Cell

Please refer to FIG. 4, which is a curve diagram showing the comparison of power conservation efficiency between a solar cell of the present invention and a conventional solar cell. The polymer solar cell that is formed using the aforesaid steps is tested and measured under 100 mW/cm² and AM (amplitude modulation) 1.5 for simulating its performance under the exposure of sunlight in view of the measurement of its I-V (current-voltage) curve, whereas the measured I-V curve is transformed into a J-V (current density-voltage) curve. As shown in FIG. 4, for the solar cell whose active layer is not doped with the nanoparticles, the power conversion efficiency is 3.7%, the open circuit voltage is 0.6V, the current density is 10.4 mA/cm², and the fill factor is 60%; and for the solar cell whose active layer is being doped with the nanoparticles, the power conversion efficiency is 4.3%, the open circuit voltage is 0.59V, the current density is 12.0 mA/cm², and the fill factor is 60%. Therefore, it is concluded that only by incorporation the nanoparticles as an additive in the active layer to optimize the surface morphology that is cooperating with corresponding heating process, the power conversion efficiency can be greatly improved without the need for any other additional manufacturing process as those conventional solar cells.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A polymer solar cell, doped with an additive of nanoparticles, comprising:
a substrate, made of a transparent glass material;
a transparent bottom electrode, disposed on the substrate;
a hole transport layer, arranged on the bottom electrode by the use of a solution process; and
an active layer, arranged on the hole transport layer and provided to be doped with a trace concentration of nanoparticles for acting as additives;
wherein an electron transporting layer/hole blocking layer/optical spacer layer and a transparent top electrode are successively disposed on the active layer in series,
wherein, after being doped with the nanoparticles and treated by an annealing treatment, the power conversion efficiency of the active layer is enhanced.

2. (canceled)

3. The polymer solar cell as claimed in claim 1, wherein the trace concentration is ranged between 0.01 mg ml⁻¹ and 0.1 mg ml⁻¹.

4. The polymer solar cell as claimed in claim 1, wherein the solution process is a process selected from the group consisting of: a spin coating process and a spray coating process.

5. The polymer solar cell as claimed in claim 1, wherein the nanoparticles are made of a copper sulfide.

6. The polymer solar cell as claimed in claim 5, wherein the nanoparticles made of copper sulfide are synthesized using the following steps: preparing a three-neck flask with 50 ml capacity for allowing the three necks to be respectively mounted by a condenser, a thermograph and sealed by a sleeve stopper while enabling the three-nech flask to be filled by 1.25 millimole of ammonium diethyldithiocarbamate (Aldrich), 10 ml of dodecanethiol (Aldrich, >98%) and 17 ml of oleic acid (Aldrich, 90%); mixing the three matters in the three-neck flask in an environment filled with argon while being heated to 110° C.; enabling 1 millimole of copper acetylacetonate (Aldrich, 99.99%) to be dispersed in 3 ml of oleic acid so as to form a blue solution while injecting the blue solution into the three-neck flask where it is heated to 180° C. and maintain at 180° C. for about 15 to 20 minutes for allowing the copper sulfide nanoparticles to grow; using a standard solvent-nonsolvent centrifugal separation process for purifying and removing excess organic matters from the nanoparticles at 4600 rpm after the temperature of the nanoparticles is dropped to 120° C.; removing the solution floating on top of the final product of the centrifugal separation process while enabling the solids deposit at the bottom of the final product to be dissolve in toluene (Acros, extra dry) under supersonic vibration; adding isopropanol (Acros, extra dry) into the solution containing the dissolved solids for segregating the nanoparticles; repeating the aforesaid steps for at least three times; and thereafter enabling the final nanoparticles to dissolve in a toluene solution so as to be keep in a grove box.

7. The polymer solar cell as claimed in claim 6, wherein the diameter of the nanoparticles of copper sulfide is ranged between 4 nanometers to 5 nanometers.

8. The polymer solar cell as claimed in claim 1, wherein the active layer is formed by the following steps: dissolving 10 mg of P3HT (Mw=69928, PDI=1.5) and 8 mg of PCBM (nano-C) in 1 ml of chlorobenzene while allowing the aforesaid mixture to be stirred and mixed for 48 hrs at 40° C. so as to prepare a P3HT/PCBM solution without nanoparticles to be used as a control group; dissolving 10 mg of P3HT and 8 mg of PCBM in 0.5 ml chlorobenzene while allowing the aforesaid mixture to be stirred and heated for 2 hrs under 40° C. so as to form an active layer solution of P3HT/PCBM/Cu₂S with Cu₂S nanoparticles to be used as a test group; performing a centrifugal separation process upon a solution formed by dissolving copper sulfide in toluene by the use of isopropanol so as to form a copper sulfide solution; adding chlorobenzene into the copper sulfide solution for preparing a new copper sulfide solution with 0.1 mg ml concentration; mixing the copper sulfide solution with 0.1 mg ml concentration with the P3HT/PCBM solution without nanoparticles, i.e. the solution of the control group, so as to form a polymer solution featuring in that: the concentration of the P3HT is 10 mg/ml, the concentration of the PCBM is 8 mg/ml and the concentration of the copper sulfide is 0.05 mg/ml; stirred and heated the polymer solution for 48 hrs in the glove box under 40° C.; using HCl (Fisher Scientific, 36%) to etch a strip of 2.5 mm in width on the glass substrate for the transparent bottom electrode that is disposed on the substrate; soaking the substrate in a solvent for allowing the same to be cleaned by a supersonic vibration process after etching; processing the substrate by plasma oxidation after cleaning; spin coating the (3,4-ethylenedioxythiophene)-poly(styrenesulfonate) (PEDOT:PSS) (Baytron P 4083) on the bottom electrode, that is made of indium tin oxide (ITO) so as to form a film of 60 nm in thickness; spin coating an active layer solution on the hole transport layer after drying the film along with the structure resulting from the aforesaid steps in an oven under 120° C.

9. The polymer solar cell as claimed in claim 8, wherein the ingredients of the solvent includes DI water/H₂O₂ (Acros, 35%) /Ammonia (Fisher Scientific, 35%), acetone (Acros, 95%), and isopropanol(Acros, 95%).

10. The polymer solar cell as claimed in claim 8, wherein the P3HT/PCBM that is doped with the copper sulfide nanoparticles is heated by the annealing treatment for 15 minutes under 110° C.
